(19) United States
(12) Patent Application Publication
(10) Pub. No.: US 2025/0379109 A1
(43) Pub. Date: Dec. 11, 2025

(54) DEVICE FOR DETECTING CRACKS IN A SEMICONDUCTOR STRUCTURE

(71) Applicant: STMicroelectronics International N.V., Geneva (CH)

(72) Inventors: Carlos Augusto Suarez Segovia, Seyssinet-Pariset (FR); Abderrezak Marzaki, Cabries (FR); Chantal Trouiller, Grenoble (FR)

(21) Appl. No.: 19/204,311

(22) Filed: May 9, 2025

(30) Foreign Application Priority Data
Jun. 7, 2024 (FR) FR2406023

(51) Int. Cl. H01L 21/66; H01L 23/528; H10D 62/10

(52) U.S. Cl. CPC H01L 22/32; H01L 23/528; H10D 62/105

(57) ABSTRACT

An embodiment crack detection device to detect a crack in an electronic chip includes a first conductive line for detecting a crack in a semiconductor structure located inside, and/or on top of, a semiconductor substrate, an interconnection structure coupled to a first surface of the semiconductor structure. The first conductive line is included within the interconnection structure and within the semiconductor structure, and includes at least one first conductive segment and at least one second conductive segment of a first metallization level of the interconnection structure electrically insulated from one another by an insulating layer. The crack detection device includes a conductive region buried deep into the semiconductor structure and an insulating region positioned between the first surface of the semiconductor structure and the buried conductive region.

### CROSS-REFERENCE TO RELATED APPLICATIONS

This application claims priority to French Application No. FR2406023, filed on Jun. 7, 2024, which application is hereby incorporated herein by reference.

### TECHNICAL FIELD

The present disclosure generally concerns the detection of defects, such as cracks or delaminations, in an electronic chip, and in particular in a semiconductor structure formed inside of, and/or on top of, a semiconductor substrate of the electronic chip.

### BACKGROUND

In industry, most electronic devices are manufactured in series. Generally, a plurality of copies of an electronic device are manufactured simultaneously inside and on top of a same semiconductor substrate, for example a same semiconductor wafer. In particular, a plurality of electronic chips are generally manufactured inside and on top of a same semiconductor substrate, for example a same semiconductor wafer. The electronic chips can then be separated, or singulated, to be able to be used, for example, alone or in a more complete electronic device. This singulation is generally performed by cutting, for example by laser cutting.

During this singulation, for example during a cutting of the semiconductor wafer, structural defects may occur on an edge of an electronic chip. Among such defects, there may be cracks, breaches, or delaminations. Such defects may lead to a failure of the electronic circuits of the electronic chip.

Further, even if defects do not appear during the manufacturing, some defects may appear during the chip lifetime, in particular on an edge of the chip, for example due to temperature changes of the electronic chip.

To detect a crack, or delamination, in an electronic chip, in particular during the manufacturing, the singulation, or even during its lifetime, the electronic chip may include a crack detector in its periphery, the crack detector being generally positioned in a sealing ring at the periphery of the electronic chip. The crack detector is ideally designed to detect a crack, or delamination, which might propagate from the edge to a region of electronic circuits of the electronic chip.

It would be desirable to be able to improve, at least partly, electronic chip crack detectors.

### SUMMARY

In an embodiment, a device comprises a first conductive line for detecting a crack in an at least one semiconductor structure. The first conductive line is comprised within an interconnection structure and within at least one semiconductor structure. The interconnection structure is coupled to a first surface of the at least one semiconductor structure. The device comprises at least one first conductive segment and at least one second conductive segment, the at least one first and second conductive segments being of a first metallization level of the interconnection structure and being electrically insulated from each other by an insulating layer. The device comprises a conductive region buried deep into each semiconductor structure, the buried conductive region being coupled to one of the at least one first conductive segment and one of the at least one second conductive segment, an insulating region being positioned between the first surface of the semiconductor structure and the buried conductive region. The device does not necessarily include the whole interconnection structure. The device for example includes at least the first conductive line, which comprises the at least one first conductive segment and the at least one second conductive segment, which are parts of the interconnection structure.

In an embodiment, a method includes transmitting a first electrical signal at a first end of the first conductive line, receiving the first electrical signal at a second end of the first conductive line, measuring a first resistance value of the received first electrical signal, and comparing the measured first resistance value with a first low resistance limit to determine the presence of a crack in the first conductive line.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A is a simplified and partial top view illustrating an example of an electronic chip comprising a crack detector;

FIG. 1B is a simplified and partial cross-section view of the electronic chip of FIG. 1A;

FIG. 1C is another simplified and partial cross-section view of the electronic chip of FIG. 1A;

FIG. 2 is a simplified and partial cross-section view illustrating a crack detection device according to an embodiment;

FIG. 3 is a simplified and partial cross-section view illustrating a crack detection device according to another embodiment;

FIG. 4 is a simplified and partial cross-section view illustrating a crack detection device according to another embodiment;

FIG. 5 is a simplified and partial cross-section view illustrating a crack detection device according to another embodiment;

FIG. 6 is a simplified and partial cross-section view illustrating a crack detection device according to another embodiment; and

FIG. 7 is a simplified and partial cross-section view illustrating a crack detection device according to another embodiment.

### DETAILED DESCRIPTION OF ILLUSTRATIVE EMBODIMENTS

An embodiment provides a crack detection device adapted to detecting a crack in an electronic chip, the crack detection device comprising a first conductive line for detecting a crack in at least one semiconductor structure located inside of, and/or on top of, a semiconductor substrate, an interconnection structure being coupled to a first surface of the at least one semiconductor structure, the first conductive line being comprised within the interconnection structure and within the at least one semiconductor structure, and comprising: at least one first conductive segment and at least one second conductive segment, said at least one first and second conductive segments being of a first metallization level of the interconnection structure and being electrically insulated from each other by an insulating layer; and a conductive region buried deep into each semiconductor structure, said buried conductive region being coupled to one of the at least one first conductive segment and one of the at least one second conductive segment, an insulating region being positioned between the first surface of the semiconductor structure and the buried conductive region.

In other words, each semiconductor structure comprises a deeply buried conductive region and an insulating region positioned between the first surface of the semiconductor structure and the buried conductive region, and the first conductive line comprises the at least one first conductive segment, the at least one second conductive segment, and the buried conductive region of each semiconductor structure. The buried conductive region is at a non-zero distance from the first surface of the semiconductor structure.

According to an embodiment, the semiconductor substrate is doped with a first conductivity type, the buried conductive region being a doped semiconductor region of a second conductivity type opposite to the first conductivity type.

According to an embodiment, each semiconductor structure comprises: a doped semiconductor well of the second conductivity type, and extending in depth from the first surface of the semiconductor structure so as to electrically couple said first surface and the buried conductive region; conductive elements coupled to the first surface of the semiconductor structure, the conductive elements comprising a first conductive element coupling the semiconductor well to the first conductive segment, and a second conductive element coupling the semiconductor well to the second conductive segment.

For example, the insulating region is surrounded by the semiconductor well.

According to an embodiment, the buried conductive region is at a depth greater than 0.5 μm, for example greater than or equal to 1 μm, or greater than or equal to 3 μm, or also greater than or equal to 5 μm.

According to an embodiment, each first conductive segment is included in a first metal stack comprising a plurality of metallization levels of the interconnection structure, and each second conductive segment is included in a second metal stack comprising a plurality of metallization levels of the interconnection structure.

According to an embodiment, the at least one semiconductor structure comprises a plurality of semiconductor structures, the at least one first conductive segment comprising a plurality of first conductive segments and the at least one second conductive segment comprising a plurality of second conductive segments, the second conductive segments between two adjacent semiconductor structures among the semiconductor structures being coupled together in the interconnection structure.

According to an embodiment, the second conductive segments are coupled together at the first metallization level of the interconnection structure.

According to an embodiment, the second metal stacks between the two adjacent semiconductor structures are coupled together by a third conductive segment of a metallization level of the interconnection structure higher than the first metallization level.

According to an embodiment, the first conductive line is also adapted to detecting a crack in the interconnection structure.

According to an embodiment, the device further comprises a second conductive line for detecting a crack in the interconnection structure, said second conductive line being comprised within the interconnection structure and being distinct from the first conductive line.

According to an embodiment, the second conductive line comprises: at least one fourth conductive segment of the first metallization level of the interconnection structure, each fourth conductive segment being insulated from the at least one first and at least one second conductive segments by the insulating layer; at least one fifth conductive segment of a metallization level of the interconnection structure higher than the first metallization level; at least one sixth conductive segment of a metallization level of the interconnection structure higher than the first metallization level; each fourth conductive segment coupling one of the at least one fifth conductive segment to one of the at least one sixth conductive segment, for example via conductive vias of the interconnection structure.

According to an embodiment, each fifth conductive segment is included in a third metal stack comprising a plurality of metallization levels of the interconnection structure from the second metallization level, and/or each sixth conductive segment is included in a fourth metal stack comprising a plurality of metallization levels of the interconnection structure from the second metallization level, for example two adjacent fourth metal stacks being coupled together at a metallization level higher than the second metallization level by a seventh conductive segment.

According to an embodiment, the second conductive line comprises a first end coupled to a first terminal of a second detection circuit and a second end coupled to a second terminal of the second detection circuit, so as to measure an electrical signal in said second conductive line to determine a presence of a crack. For example, the first end and/or the second end of the second conductive line is coupled to, or corresponds to, the at least one fifth conductive segment.

According to an embodiment, the first conductive line comprises a first end coupled to a first terminal of a first detection circuit and a second end coupled to a second terminal of the first detection circuit, so as to measure an electrical signal in said first conductive line to determine a presence of a crack. For example, the first end and/or the second end of the first conductive line is coupled to, or corresponds to, the at least one first conductive segment.

According to an embodiment, the second terminal of the second detection circuit is electrically insulated from the second terminal of the first detection circuit, for example the first terminal of the second detection circuit is electrically coupled to the first terminal of the first detection circuit.

According to an embodiment, the insulating layer comprises a material with a lower dielectric constant than the dielectric constant of silicon dioxide.

An embodiment provides an electronic chip comprising: —a semiconductor substrate; at least one semiconductor structure located inside, and/or on top of, the semiconductor substrate; an interconnection structure coupled to a first surface of the at least one semiconductor structure; and a crack detection device such as described in the foregoing.

According to an embodiment, the at least one semiconductor structure comprises a plurality of semiconductor structures, at least one semiconductor among said semiconductor structures comprising a vertical gate structure of a buried selection transistor of an integrated memory cell with a trench selection transistor.

According to an embodiment, the crack detection device is positioned at the periphery of the electronic chip, for example around an electronic circuit region of the electronic chip, for example in a sealing ring of the electronic chip.

An embodiment provides a method of use of the crack detection device such as described in the foregoing, the method comprising: the transmission of a first electrical signal at a first end of the first conductive line; the reception of the first electrical signal at a second end of the first conductive line, and he measurement of a first resistance value of the received first electrical signal; the comparison of the measured first resistance value with a first low resistance limit to determine a presence of a crack in the first conductive line.

According to an embodiment, the method comprises: the transmission of a second electrical signal at a first end of the second conductive line; the reception of the second electrical signal at a second end of the second conductive line, and the measurement of a second resistance value of the received second electrical signal; the comparison of the measured second resistance value with a second low resistance limit to determine a presence of a crack in the second conductive line; the first low resistance limit being for example higher than the second low resistance limit.

An embodiment provides a method of co-integration of a plurality of semiconductor structures inside, and/or on top of, a same semiconductor substrate, the method further comprising the forming of an interconnection structure coupled to a first surface of the semiconductor structures, and of a crack detection device such as described in the foregoing, at least one semiconductor structure among the semiconductor structures comprising a vertical gate structure of a buried selection transistor of an integrated memory cell with a trench selection transistor.

Further embodiments and details will be described in detail herein. Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, not all the manufacturing steps and details of the semiconductor structures are described, being achievable with usual methods of manufacturing semiconductor structures inside and/or on top of a semiconductor substrate. Further, the manufacturing steps and the details of the interconnection structures are not described, being achievable with usual interconnection structure manufacturing methods.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

In the following description, the terms “insulating” and “conductive” respectively signify, unless otherwise specified, electrically insulating and electrically conductive. Similarly, the term “insulate” means, unless otherwise specified, electrically insulate.

In the following description, unless otherwise specified, when reference is made to a chip, reference is made to an electronic chip, when reference is made to a via, reference is made to a conductive via, when reference is made to a substrate, reference is made to a semiconductor substrate, and when reference is made to a well, reference is made to a semiconductor well.

In the following description, when reference is made to a crack detection device or, short, to a crack detector, reference is made to a device capable of detecting a structural defect which is not limited to a crack, for example it may be a breach or a delamination. For the sake of brevity, when reference is made to a crack, this can include a breach, a delamination, or any other similar structure defect.

In the following description, by “buried”, there is meant buried deep in the semiconductor structure.

In the following description, a first metallization level of an interconnection structure generally corresponds to a metallization level closest to a semiconductor substrate to which the interconnection structure is coupled. A second metallization level of the interconnection structure corresponds to a metallization level further away from the semiconductor substrate than the first metallization level. More generally, a metallization level N+1 corresponds to a metallization level further away from the semiconductor substrate than metallization level N.

The present disclosure for example concerns the detection of cracks that may propagate from an edge of an electronic chip to electronic circuits of the electronic chip.

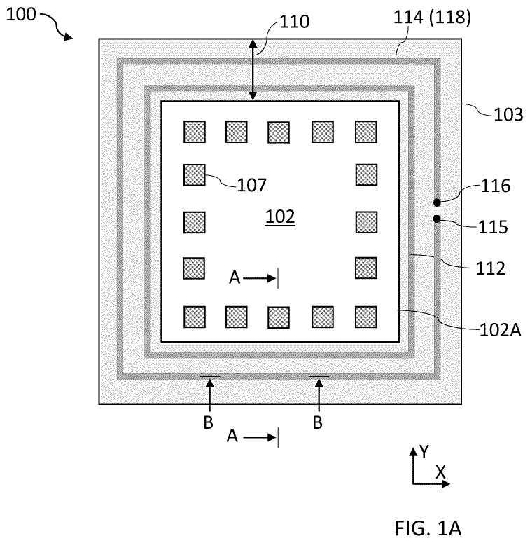

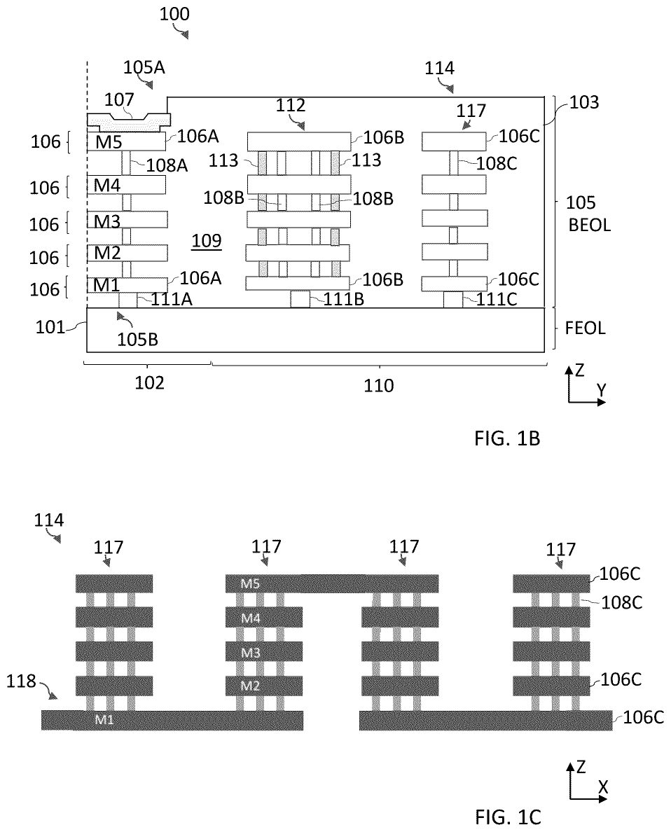

FIG. 1A is a simplified and partial top view illustrating an example of an electronic chip 100. FIG. 1B is a simplified and partial cross-section view of the electronic chip 100 of FIG. 1A. FIG. 1C is another simplified and partial cross-section view of the electronic chip of FIG. 1A. FIG. 1C shows a detail of a crack detector integrated in the electronic chip. The cross-section view of FIG. 1B is obtained along the cross-section plane A-A indicated in FIG. 1A. The cross-section view of FIG. 1C is obtained along the cross-section plane B-B indicated in FIG. 1A.

Electronic chip 100 comprises a semiconductor layer 101, which may correspond to a semiconductor substrate, for example made of silicon, or to the semiconductor layer of a substrate of silicon on insulator, “SOI”, type. Semiconductor layer 101 may include one or a plurality doped wells.

Electronic circuits of chip 100 are arranged inside and/or on top of semiconductor layer 101, this part of the chip being generally referred to as “FEOL”, for “front end of line”. For the sake of clarity, the electronic circuits of chip 100 are not shown in FIGS. 1A, 1B, and 1C, but are all arranged in an electronic circuit region, or circuit region 102, of chip 100 delimited by a circumference 102A. In other words, circuit region 102 comprises all the electronic circuits of chip 100. The circuit region 102 of chip 100 is, for example, a central region of chip 100, as shown in the view of FIG. 1A.

Chip 100 further comprises an interconnection structure 105 above semiconductor layer 101, for example in contact with, or coupled to, semiconductor layer 101. This interconnection structure 105 is generally referred to as a back end of line, “BEOL”, interconnection structure. Interconnection structure 105 comprises a plurality of metallization levels. Five metallization levels M1, M2, M3, M4, M5 have been shown in FIGS. 1B and 1C, although this is not limiting, as the number of metallization levels may be smaller or greater than five.

Each metallization level comprises at least one first segment 106A of a conductive layer 106, for example a metal layer, each first segment 106A forming a conductive track. The conductive tracks 106A of the different metallization levels of interconnection structure 105 are electrically coupled to one another and/or to connection pads 107 and/or to the electronic circuits of chip 100 by conductive vias 108A, for example metal vias. The conductive tracks 106A of the various metallization levels of interconnection structure 105 are preferably positioned in circuit region 102. Thus, interconnection structure 105 enables to couple the electronic circuits of chip 100 to one another and/or to connection pads 107. Connection pads 107, which may be referred to as “pads” for short, form part of interconnection structure 105. Pads 107 are arranged at the top metallization level of interconnection structure 105 in the example of FIG. 1B, or last metallization level, which corresponds to metallization level M5 in this example. In other words, pads 107 are arranged at an upper surface 105A (first surface) of interconnection structure 105, a lower surface 105B (second surface) of the interconnection structure, opposite to the first surface 105A, being coupled to, or in contact with, semiconductor layer 101.

Pads 107 may be distributed in substantially ring-shaped manner, here a square-shaped ring, in the circuit region 102 of chip 100 and, more precisely, in a region of interconnection structure 105 comprised within the circuit region 102 of chip 100. Other arrangements can be envisaged by those skilled in the art.

Interconnection structure 105 further comprises an insulating layer 109, which is generally a stack of a plurality of insulating layers, separating the different metallization levels, the conductive layers 106 and the conductive vias being embedded in insulating layer 109. Insulating layer 109 may be made of an oxide, for example a silicon oxide.

The conductive track 106A at the first metallization level M1 of interconnection structure 105 may be coupled to semiconductor layer 101 by a conductive via or by a contact 111A, or any other electrical connection element.

Chip 100 comprises a sealing region 110, or sealing ring, at the periphery of chip 100, that is, between circuit region 102 and the edge 103 of chip 100. Thus, sealing ring 110 surrounds the circuit region 102 of chip 100. The sealing ring 110 has a ring shape in top view. Sealing ring 110 is arranged in interconnection structure 105, at the periphery of chip 100. Sealing ring 110 thus forms part of interconnection structure 105, although it is not used to connect the electronic circuits of chip 100 to one another and/or to pads 107. Preferably, chip 100 comprises no electronic circuits in sealing ring 110. In other words, the circuit region 102 of chip 100 is laterally delimited, in the interconnection structure 105, by sealing ring 110.

A targeted function of sealing ring 110 is to avoid the propagation of cracks from the edge 103 of chip 100 to the circuit region 102 of chip 100. Another targeted function of sealing ring 110 may be to block the propagation of moisture from the outside of chip 100, that is, from the edge 103 of chip 100, to the electronic circuits in the circuit region 102 of chip 100. Another targeted function of sealing ring 110 may be to detect a crack in electronic chip 100.

To fulfill one or a plurality of these functions, sealing ring 110 may include one or a plurality of sealing elements 112, each sealing element having a ring shape in top view. A sealing element has been shown in FIGS. 1A, 1B, and 1C, although there may be a plurality thereof. Where there is a plurality of sealing elements, they may be substantially concentric. One sealing element may be adapted to stopping the propagation of cracks, another sealing element may be adapted to blocking moisture ingress, and/or one sealing element may be adapted to performing both functions of stopping crack propagation and of blocking moisture ingress.

Sealing element 112 extends in height from the first metallization level M1, above semiconductor layer 101, to the top metallization level, level M5 in the shown example, although the top metallization level may be different from M5, for example M6, M7 or more, or even M4 or less.

The shown sealing element 112 forms a closed loop around the circuit region 102 of chip 100. In other words, sealing element 112 completely surrounds the circuit region 102 of chip 100.

In the example of embodiment shown in FIG. 1B, sealing element 112 comprises second segments 106B of the conductive layers 106 of interconnection structure 105. More specifically, sealing element 112 comprises at least one second segment 106B of the conductive layer 106 of each metallization level M1-M5 of interconnection structure 105. The second segments 106B of the various metallization levels are embedded in insulating layer 109. Each second segment 106B of conductive layer 106 forms a ring-shaped conductive plate at each metallization level. For example, each ring-shaped conductive plate 106B extends in a plane substantially parallel to semiconductor layer 101.

The successive ring-shaped conductive plates 106B of sealing element 112 are vertically coupled to one another by one or a plurality of conductive elements, for example: conductive vias 108B of interconnection structure 105: the vias may be in cylindrical form or be elongated in the form of bars or of lines; and/or ring-shaped conductive strips 113 which extend continuously between two successive ring-shaped conductive plates 106B: in other words, the ring-shaped conductive strips 113 join two successive ring-shaped conductive plates 106B in the Z direction perpendicular to the XY plane of semiconductor layer 101.

Sealing element 112 may be coupled to semiconductor layer 101 via the conductive plate 106B of the first metallization level M1 by a conductive via or a contact 111B, or any other electrically-conductive element.

In order to detect cracks in chip 100, sealing ring 110 includes a crack detector 114. Crack detector 114 is thus positioned at the periphery of chip 100, around circuit region 102.

Crack detector 114 is arranged in interconnection structure 105. In other words, interconnection structure 105 includes crack detector 114. Crack detector 114 extends in height from the first metallization level M1, above semiconductor layer 101, to the top metallization level M5.

As shown in FIG. 1A, crack detector 114 may be arranged in a region located between the edge 103 of chip 100 and sealing element 112. Thus, if a crack appears at the edge 103 of chip 100 and propagates towards circuit region 102, the crack may be detected by crack detector 114 before sealing element 112. Other configurations can be envisaged by those skilled in the art, with one or a plurality of sealing elements and/or one or a plurality of crack detectors, as described hereafter. Preferably, the crack detector detects a crack before it reaches the circuit region 102 of chip 100.

Crack detector 114 comprises a conductive structure 118, or conductive line, which preferably forms an open loop. By measuring an electrical parameter, for example a conductivity or an electrical resistance, between a first terminal, or node, 115 of conductive line 118 and a second terminal, or node, 116 of conductive line 118, cracks can be detected by crack detector 114. Crack detector 114 may comprise a detection circuit (not shown), which may be coupled to the first and second terminals 115, 116, to detect a change in an electrical parameter in conductive line 118 indicating the presence of a crack. The detection circuit may be implemented in electronic chip 100, for example in circuit region 102, or in a circuit external to electronic chip 100.

In the example of embodiment shown in FIGS. 1B and 1C, conductive line 118 is built in interconnection structure 105, and it comprises a plurality of metal stacks 117, each metal stack including third segments 106C of the conductive layers 106 of interconnection structure 105 and conductive vias 108C between the third segments 106C of the different metallization levels. The third segments 106C of the different metallization levels are embedded in insulating layer 109.

Two adjacent metal stacks 117 are coupled by one or a plurality of third segments 106C of one of the metallization levels. In the example shown in FIG. 1C, adjacent metal stacks 117 are coupled to one another by third segments 106C of the first metallization level M1 or by third segments 106C of the last metallization level M5. There have been illustrated as an example in FIG. 1C four metal stacks 117 of crack detector 116, but crack detector 114 may comprise more, for example to surround electronic chip 100.

Crack detector 114 may be coupled to semiconductor layer 101 via the third segment 106C of the first metallization level M1 by a conductive via or a contact 111C, or any other electrically-conductive element.

Although this is not shown in FIGS. 1A, 1B, and 1C, sealing ring 110 may comprise a plurality of sealing elements similar to the previously-described sealing element 112, for example an inner sealing element arranged in interconnection structure 105 around the circuit region 102 and an outer sealing element arranged in interconnection structure 105 around the inner sealing element. Sealing ring 110 may then comprise an intermediate crack detector, for example similar to the previously-described crack detector 114, arranged in interconnection structure 105 between the inner sealing element and the outer sealing element. The presence of inner and outer sealing elements and of an intermediate crack detector between these two sealing elements enables to detect that cracks have propagated from the edge 103 of the electronic chip through the outer sealing element. Sealing ring 110 may comprise an inner crack detector arranged in interconnection structure 105 around, or on the edges of, circuit region 102 and surrounded by sealing element 112, or the inner sealing element. Such an inner crack detector enables to detect that cracks have propagated from the edge 103 of chip 100 through the sealing element(s) and are likely to reach circuit region 102.

Known crack detectors, such as those described in the foregoing, enable to detect a crack from the first metallization level M1 all the way to one or a plurality of higher metallization level(s). Known crack detectors do not enable to detect a crack under the first metallization level M1, and in particular do not enable to detect a crack in the semiconductor layer, or the semiconductor substrate, under the interconnection structure.

The inventors provide a device for detecting cracks in a semiconductor structure enabling to address the previously-described improvement needs, and to overcome all or part of the disadvantages of the previously-described crack detectors.

In particular, the inventors provide a crack detection device enabling to detect a crack in the semiconductor substrate, under the interconnection structure, that is, in the so-called FEOL part, or in a semiconductor structure formed inside and/or on top of the semiconductor substrate.

It would be advantageous for the crack detection device to also be able to detect a crack in the interconnection structure, that is, in the BEOL part. In particular, it would be advantageous for the crack detection device to be able to tell a crack in the interconnection structure (BEOL part) from a crack in the semiconductor substrate (FEOL part).

Embodiments of crack detection devices will be described hereafter. The described embodiments are non-limiting and different variants will occur to those skilled in the art based on the indications of the present disclosure.

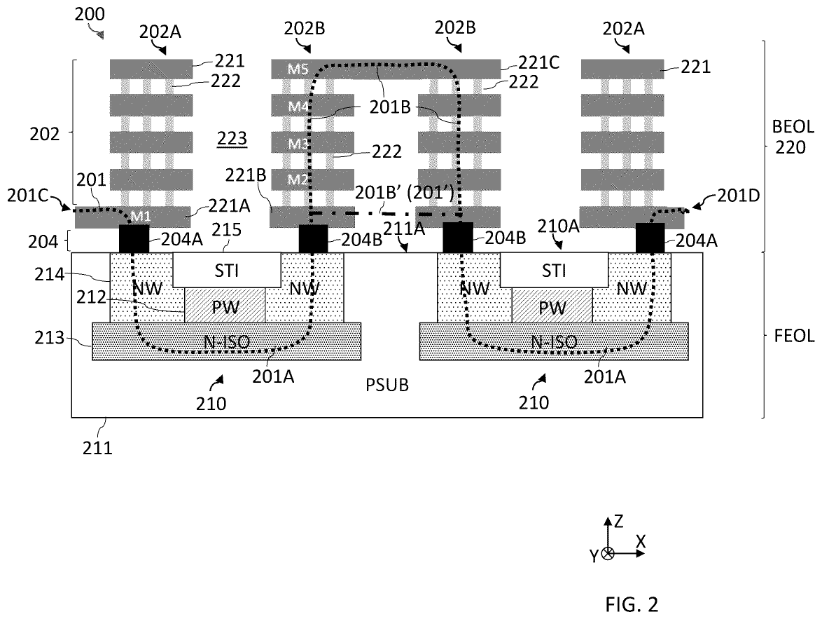

FIGS. 2 to 7 described in the following describe examples of semiconductor structures of CMOS, for “complementary metal-oxide-semiconductor”, type, formed inside and/or on top of a semiconductor substrate: for example, a structure of “triple well” type, a vertical gate structure with an implant under the gate, for example to form a trench transistor. These examples of semiconductor structures are not limiting, and other CMOS-type semiconductor structures can be envisaged by those skilled in the art. Further, a plurality of different semiconductor structures may be formed inside and/or on top of the semiconductor substrate.

In FIGS. 2 to 7 described in the following, the semiconductor substrate is typically a P-type doped silicon substrate. In other words, the first doping type, or conductivity type, is of type P. As a variant, the semiconductor substrate may be N-type doped, that is, the first doping type, or conductivity type, may be type N, in which case those skilled in the art will be capable of adapting the doping type of the semiconductor wells, regions, and layers in the devices, structures, and methods described in the following. The semiconductor substrate may be made of another material than silicon.

The detection devices of FIGS. 2 to 7 are preferably integrated in an electronic chip, for example an electronic chip similar to that of FIGS. 1A and 1B. The detection devices of FIGS. 2 to 7 may then form part of an interconnection structure of the electronic chip. In particular, the detection devices of FIGS. 2 to 7 may be positioned at the periphery of the electronic chip, around an electronic circuit region of the chip. For example, the detection devices of FIGS. 2 to 7 may be integrated in a sealing ring, in association with one or a plurality of sealing elements, similarly to what is described in relation with FIGS. 1A and 1B. The different variants of a sealing ring described in relation with FIGS. 1A and 1B may also apply. Further, in FIGS. 2 to 7, five metallization levels M1-M5 have been shown in the interconnection structure, although there may be six levels (M1-M6) or seven levels (M1-M7), or more, or even less than five levels.

Each of the crack detection devices 200, 300, 400 of FIGS. 2 to 4 differs from the crack detector 114 of FIG. 1C mainly in that the conductive line (first conductive line) of the detection device is not only formed in the interconnection structure, but also comprises one or a plurality of conductive portions in the semiconductor substrate, or in semiconductor structures formed inside and/or on top of the semiconductor substrate, these conductive portions forming an electrical conduction channel. In particular, each of the crack detection devices of FIGS. 2 to 4 differs from the crack detector 114 of FIG. 1C in that the metal stacks are not coupled together not necessarily by segments of the conductive layer of the first metallization level M1, but are coupled together by the conductive portions in the semiconductor substrate.

In each of FIGS. 2 to 4, semiconductor structures are formed inside and/or on top of the semiconductor substrate. These are generally CMOS-type semiconductor structures. The conductive line of each of the crack detection devices of FIGS. 2 to 4 not only runs through the interconnection structure, that is, not only comprises segments of conductive layers of the interconnection structure, but also comprises conductive portions in these semiconductor structures.

Different semiconductor structures 210, 310, 410 will now be described in the following description of FIGS. 2 to 4, as well as different conductive lines 201, 301, 401 which depend on the type of semiconductor structure. In particular, the depth of the conductive line, and thus the crack detection depth, may depend on the type of semiconductor structure.

In FIGS. 2 to 4, conductive line 201, 301, 401 (first conductive line) is symbolized by a dotted line, which enables to visualize one conductive path among a plurality of possible conductive paths along conductive line 201, 301, 401. Conductive line 201, 301, 401 is thus not limited to this dotted line.

FIG. 2 is a simplified and partial cross-section view illustrating a crack detection device 200 according to an embodiment.

Each semiconductor structure 210 of FIG. 2 is a structure of triple-well type.

Each triple-well structure 210 enables to electrically insulate a doped semiconductor well 212 (PW) of a first doping type, which is the same doping type as that of semiconductor substrate 211 (PSUB), in the shown example a P-type doping, by means of doped semiconductor regions 213, 214 of the second doping type opposite to the first doping type. In the shown example, the second doping type is type N.

The semiconductor regions 213, 214 comprise: a buried doped semiconductor region 213 (N-ISO) of the second doping type, enabling to insulate in depth well 212 from semiconductor substrate 211; and a ring-shaped semiconductor well 214 (NW), or ring-shaped semiconductor region, doped with the second doping type, laterally surrounding semiconductor well 212 (along the X and Y directions), enabling to laterally insulate it.

Throughout the description, the term “ring-shaped” designates a ring shape which is not necessarily circular, but which may for example be square or rectangular, more generally a geometric area delimited by an inner perimeter and an outer perimeter substantially parallel to each other.

Ring-shaped semiconductor well 214 extends from the upper surface 211A of semiconductor substrate 211 in depth, preferably down to buried semiconductor region 213. Thus, ring-shaped semiconductor well 214 is preferably in contact with buried semiconductor region 213.

In the example of FIG. 2, the upper surface 210A of semiconductor structure 210 corresponds to the upper surface 211A of semiconductor substrate 211.

Further, an insulating trench 215 (STI), for example of shallow trench insulation type, known under the term STI, is located above semiconductor well 212 and is surrounded by ring-shaped semiconductor well 214. Thus, semiconductor well 212 is buried, and it is electrically insulated in its upper portion by insulating trench 215. Semiconductor well 212 is thus entirely surrounded by regions which electrically insulate it. Insulating trench 215 may extend on either side of semiconductor well 212 into ring-shaped semiconductor well 214.

A simplified example of a method of forming a semiconductor structure 210 comprises: an etching from the upper surface 211A of semiconductor substrate 211 to form a shallow trench in semiconductor substrate 211, then a filling of this trench, for example with silicon oxide, to form insulating trench 215; a deep implantation into semiconductor substrate 211 to form buried semiconductor region 213 (N-ISO), this implantation being of the second doping type, in this example of type N; an implantation from the upper surface 211A of semiconductor substrate 211 to form ring-shaped semiconductor well 214 (NW), this implantation being of the second doping type, in this example of type N; an implantation into semiconductor substrate 211 through insulating trench 215 and into the central portion delimited by ring-shaped semiconductor well 214 to form semiconductor well 212, this implantation being of the first doping type, in this example of type P.

The order of the last two steps may be reversed.

Ring-shaped semiconductor well 214 is preferably implanted with an energy enabling to reach in depth buried semiconductor region 213, so as to form with buried semiconductor region 213 a continuous N-type semiconductor region to insulate P-type semiconductor well 212.

As an example, buried semiconductor layer 213 may form a source plane, or a source region, for a vertical transistor, and semiconductor well 212 may contain a memory cell.

In such a triple-well structure, PN junctions of polarities opposite to P-type well 212, formed with N-type semiconductor regions 213, 214, enable to electrically insulate well 212, which is further insulated by insulating trench 215. The current is thus conducted through buried semiconductor region 213 via ring-shaped semiconductor well 214. Semiconductor regions 213, 214 thus form a conductive portion 201A, or electrical conduction channel, in semiconductor substrate 211, in each semiconductor structure 210.

The conductive portion 201A of each semiconductor structure 210 corresponds to a first portion of a conductive line 201 (first conductive line) of detection device 200. Conductive line 201 thus includes the semiconductor regions 213, 214 of semiconductor structures 210, that is, the buried semiconductor region 213 and the ring-shaped semiconductor well 214 of each semiconductor structure 210.

Conductive line 201 further comprises all or part of a plurality of metal stacks 202. Metal stacks 202 form part of an interconnection structure 220 (BEOL) positioned above semiconductor substrate 211. Each metal stack 202 comprises conductive segments 221 at each metallization level M1-M5 of interconnection structure 220 and conductive vias 222 between the conductive segments 221 of the different metallization levels M1-M5. A conductive segment 221 of a metallization level generally corresponds to a segment, or a portion, of a conductive layer, for example a metal layer, formed in this metallization level. Conductive segments 221 and conductive vias 222 are embedded in an insulating layer 223.

In the shown example, the portions of conductive line 201 which are formed in metal stacks 202 include: a conductive segment 221A (first conductive segment) of the first metallization level M1 for each of two first metal stacks 202A; and a plurality of conductive segments 221 of a plurality of metallization levels coupled by conductive vias 222 for each of two second metal stacks 202B.

Conductive line 201 further comprises contacts 204. Contacts 204 are considered to form part of interconnection structure 220. Contacts 204 comprise first contacts 204A coupling each of the semiconductor structures 210 to the conductive segment 221A of one of the first metal stacks 202A, and second contacts 204B coupling each of the semiconductor structures 210 to one of the second metal stacks 202B, more specifically to a conductive segment 221B (second conductive segment) of one of the second metal stacks 202B. Each of these contact connections is made at the first metallization level M1. Contacts 204 are coupled, for example connected, to the upper surface 210A of semiconductor structure 210, which here corresponds to the upper surface 211A of semiconductor substrate 211. In particular, contacts 204 are coupled, for example connected, to the ring-shaped semiconductor wells 214 of semiconductor structures 210. Thus, each ring-shaped semiconductor well 214 is coupled to first and second metal stacks 202A, 202B via contacts 204. Thus, the first and second metal stacks 202A, 202B are not coupled to each other by conductive segments at the first metallization level M1, as in FIG. 1C, but by conductive portion 201A in semiconductor structure 210, that is, buried semiconductor region 213 and ring-shaped semiconductor well 214.

The second metal stacks 202B between the two semiconductor structures 210 are coupled together at the last metallization level M5 by a conductive segment 221C (third conductive segment) which is continuous between these second metal stacks. Thus, a second portion 201B of conductive line 201 includes all the metallization levels M1-M5 of the second metal stacks 202B, that is, the conductive segments 221 and the conductive vias 222 of all metallization levels, including the continuous conductive segment 221C between the second metal stacks 202B at the last metallization level M5.

Conductive line 201 thus comprises: the first portions 201A formed by the N-doped semiconductor regions 213, 214 of semiconductor structures 210; the second portion 201B between the first portions 201A, the second portion being formed by the second metal stacks 202B coupled together by the conductive segment 221C at the last metallization level M5 of interconnection structure 220, the second portion 201B being coupled to each of the first portions 201A by one of the second contacts 204B; the conductive segments 221A of the first metal stacks 202A, each coupled to one of the first portions 201A by one of the first contacts 204A.

Conductive line 201 may be coupled to a detection circuit (not shown). For example, a first end 201C of conductive line 201 may be coupled to a first terminal of the detection circuit at the first metallization level M1, and a second end 201D of conductive line 201 may be coupled to a second terminal of the detection circuit at the first metallization level M1, but the connection may be achieved at any other metallization level. The detection circuit may be configured to detect a change in an electrical parameter in conductive line 201 indicating the presence of a crack.

In the example of FIG. 2, one end of each conductive segment 221A may correspond to one of the first 201C and second 201D ends of conductive line 201.

Such a detection device 200 enables to detect a crack in depth all the way down to a buried semiconductor region of semiconductor substrate 211, buried semiconductor region 213 in the example of FIG. 2. More generally, detection device 200 enables to detect a crack along conductive line 201, between buried semiconductor region 213 and upper metallization level M5. To detect a crack, a change in an electrical parameter in conductive line 201 may be determined, for example a resistance increase when conductive line 201 is damaged by a crack in one of semiconductor regions 213, 214, or even an infinite resistance when conductive line 201 is interrupted. A low resistance limit may be defined to determine whether a crack has occurred.

Buried semiconductor region 213 may be located at a depth ranging up to 3 μm or even up to 5 μm in semiconductor substrate 211. Thus, the detection device 200 can detect a crack down to a 5-μm depth.

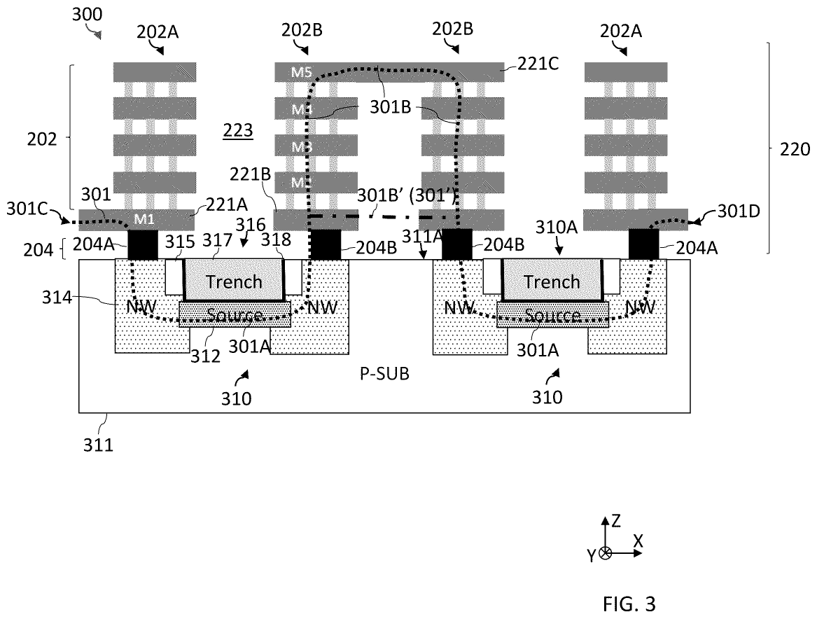

FIG. 3 is a simplified and partial cross-section view illustrating a crack detection device 300 according to another embodiment.

The crack detection device 300 of FIG. 3 has many features in common with the crack detection device 200 of FIG. 2 and only the differences between the two crack detection devices are detailed in the following description.

The crack detection device 300 of FIG. 3 differs from the crack detection device 200 of FIG. 2 mainly by semiconductor structures 310, which are of vertical gate type, with an implantation region buried under the gate.

Each semiconductor structure 310 comprises a vertical gate structure 316 which extends in depth in semiconductor substrate 311, from the upper surface 311A of semiconductor substrate 311.

In the example of FIG. 3, the upper surface 310A of semiconductor structure 310 corresponds to the upper surface 311A of semiconductor substrate 311.

Vertical gate structure 316 comprises a conductive trench 317, that is, a trench filled with a conductive material, for example polycrystalline silicon (polysilicon), the bottom and the sides of the trench being insulated by an insulating layer 318, for example of silicon oxide.

Conductive trench 317 is at least partially surrounded by an insulating trench 315, for example of shallow trench insulation type, for example of the same type as the insulating trench 215 of FIG. 2.

The semiconductor structure 310 further comprises a buried semiconductor region 312 (Source) doped with the second doping type, that is, opposite to the doping type of semiconductor substrate 311. In the shown example, semiconductor substrate 311 is P-type doped and buried semiconductor region 312 is N-type doped. Buried semiconductor region 312 extends in depth from the bottom of gate structure 316. As a variant, this buried semiconductor region 312 may be located around and below gate structure 316.

Insulating trench 315 (STI), conductive trench 317, and buried semiconductor region 312 are laterally surrounded (in the X and Y directions) by a doped ring-shaped semiconductor well 314 (NW) of the second doping type, in the shown example of type N.

A simplified example of a method of forming a semiconductor structure 310 comprises: an etching from the upper surface 311A of semiconductor substrate 311 to form a shallow trench in semiconductor substrate 311, then a filling of this trench, for example with silicon oxide, to form insulating trench 315; an etching through insulating trench 315 from the upper surface 311A of semiconductor substrate 311 to form a trench intended to be filled with a conductive material to form the future conductive trench 317; a deep implantation in semiconductor substrate 311 under the trench to form buried semiconductor region 312, this implantation being of the second doping type, in the example of type N; an implantation from the upper surface 311A of semiconductor substrate 311 to form ring-shaped semiconductor well 314 around insulating trench 315 and buried semiconductor region 312, this implantation being of the second doping type, in the example of type N; a forming of an insulating layer 318 on the bottom and the sides of the trench, then a filling with the conductive material, for example polysilicon, of the trench covered with insulating layer 318 to form conductive trench 317.

The order of the last two steps can be reversed.

In each semiconductor structure 310, the current is conducted through buried semiconductor region 312 via ring-shaped semiconductor well 314, conductive trench 317 being insulated by insulating layer 318. Thus, semiconductor regions 312, 314 form a conductive portion 301A in semiconductor substrate 311, in each semiconductor structure 310, this conductive portion 301A forming a first portion of a conductive line 301.

This type of vertical gate structure may correspond to the vertical gate structure of a buried transistor, used for example as a selection or access transistor of a memory cell, for example for an eSTM (embedded Select in-Trench Memory) memory.

The other features and variants described in relation with FIG. 2, for example the metal stacks 202, the contacts 204, the second portion 201B of the conductive line, may apply to the embodiment of FIG. 3. In particular, similarly to the embodiment of FIG. 2, conductive line 301 further comprises all or part of metal stacks 202 forming part of an interconnection structure 220 (BEOL) positioned above semiconductor substrate 311. Further, similarly to the embodiment of FIG. 2, a first contact 204A and a second contact 204B, positioned on the ring-shaped semiconductor wells 314 of semiconductor structures 310, enable to couple each of the semiconductor structures 310 respectively to a first metal stack 202A and a second metal stack 202B, the second metal stacks 202B between the two semiconductor structures 310 being coupled together at the last metallization level M5, or at any other metallization level.

Conductive line 301 comprises: conductive portions 301A, or first portions, formed by the N-doped semiconductor regions 312, 314 of semiconductor structures 310; a second portion 301B between the first portions 301A, the second portion being similar to the second portion 201B described in relation with FIG. 2, the second portion 301B being coupled to each of the first portions 301A by one of the second contacts 204B; and the conductive segments 221A of the first metal stacks 202A, each coupled to one of the first portions 301A by one of the first contacts 204A.

Similarly to what is described in relation with FIG. 2, conductive line 301 may be coupled to a detection circuit (not shown). For example, a first end 301C of conductive line 301 may be coupled to a first terminal of the detection circuit at the first metallization level M1, and a second end 301D of conductive line 301 may be coupled to a second terminal of the detection circuit at the first metallization level M1, but the connection may be made at any other metallization level. The detection circuit may be configured to detect a change in an electrical parameter in conductive line 301 indicating the presence of a crack. One end of each conductive segment 221A may correspond to one of the first 301C and second 301D ends of conductive line 301.

Such a detection device 300 enables a crack to be detected in depth all the way down into a buried semiconductor region of semiconductor substrate 311, buried semiconductor region 312 in the example of FIG. 3. More generally, detection device 300 enables to detect a crack along conductive line 301, between buried semiconductor region 312 and upper metallization level M5. To detect a crack, a change in an electrical parameter in conductive line 301 may be determined, for example an increase in the resistance when conductive line 301 is damaged by a crack in one of semiconductor regions 312, 314, or even an infinite resistance when conductive line 301 is interrupted. A low resistance limit may be defined to determine whether a crack has occurred.

Buried semiconductor region 312 may be located at a depth ranging up to 0.5 μm, or even to 1 μm. Thus, detection device 300 can detect a crack down to a 1-μm depth.

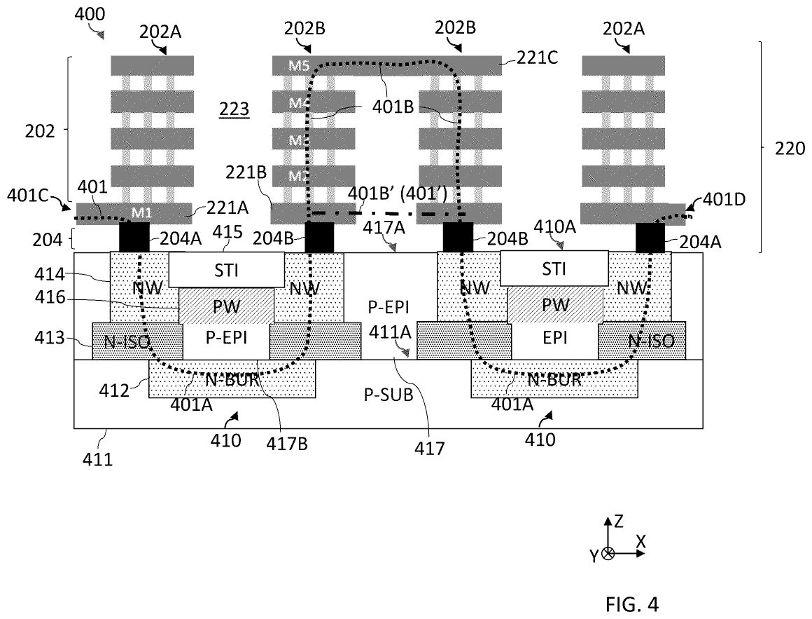

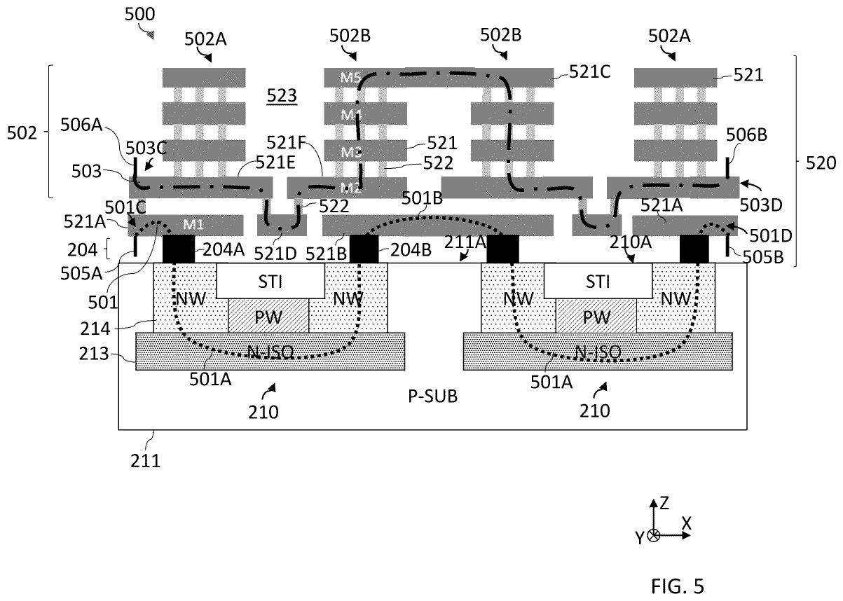

FIG. 4 is a simplified and partial cross-section view illustrating a crack detection device 400 according to another embodiment.

The crack detection device 400 of FIG. 4 has many features in common with the crack detection device 200 of FIG. 2 and only the differences between the two crack detection devices are detailed in the following description.

The crack detection device 400 of FIG. 4 differs from the crack detection device 200 of FIG. 2 mainly by semiconductor structures 410, which each comprise an epitaxial layer 417 on semiconductor substrate 411 in which P-and N-type implantations are performed, as detailed in the following. This enables to have semiconductor regions buried even deeper than in FIG. 2.

Each semiconductor structure 410 comprises a first buried semiconductor region 412 (N-BUR) formed in a semiconductor substrate 411 and doped with the second doping type, opposite to the doping type of semiconductor substrate 411. In the shown example, semiconductor substrate 411 is P-type doped and first buried semiconductor region 412 is N-type doped. For example, the first buried semiconductor region 412 is flush with the upper surface 411A of semiconductor substrate 411.

Semiconductor structure 410 further comprises an epitaxial layer 417 (P-EPI) positioned on the upper surface 411A of semiconductor substrate 411. Epitaxial layer 417 is lightly doped with the first doping type, in the example type P.

An insulating trench 415, for example of shallow trench insulation (STI) type, is formed from the upper surface 417A of epitaxial layer 417. Insulating trench 415 is, for example, of the same type as the insulating trench 215 of FIG. 2.

In this semiconductor structure 410, the upper surface 410A of semiconductor structure 410 corresponds to the upper surface 417A of epitaxial layer 417, and not to the upper surface 411A of semiconductor substrate 411.

A semiconductor well 416 is located in epitaxial layer 417 under insulating trench 415. Semiconductor well 416 is more heavily doped with the first doping type than epitaxial layer 417, in the example of type P.

Under semiconductor well 416, between semiconductor well 416 and the first buried semiconductor region 412, a portion 417B of the lightly-doped epitaxial layer 417 of the first doping type is preferably kept, to form a diode blocking the flowing of current. Portion 417B is surrounded with a second doped buried semiconductor region 413 (N-ISO) of the second doping type, in the example type N.

Portion 417B of epitaxial layer 417 is narrower than the first buried semiconductor region 412, and is centered with respect to the first buried semiconductor region 412, so that the second buried semiconductor region 413 comprises areas of contact with the first buried semiconductor region 412. Thus, an electrical continuity, or an electrical conduction channel, is obtained.

Insulating trench 415 (STI) and semiconductor well 416 are laterally surrounded (in the X and Y directions) by a doped ring-shaped semiconductor well 414 (NW) of the second doping type, in this example of type N.

Ring-shaped semiconductor well 414 extends from the upper surface 417A of epitaxial layer 417 down to the second buried semiconductor region 413. Thus, ring-shaped N-type semiconductor well 414 is in contact with the second N-type buried semiconductor region 413, itself in contact with the first N-type buried semiconductor region 412. Thus, N-doped semiconductor regions 412, 413, 414 form a conductive portion 401A in each semiconductor structure 410, insulated from the other regions which are either of type P, or insulating. This conductive portion 401A forms a first portion of a conductive line 401.

Such a semiconductor structure 410 enables to have a buried semiconductor region located deeper than the previously-described semiconductor structures, for example at a depth that may be greater than 5 μm.

A simplified example of a method of forming a semiconductor structure 410 comprises: an implantation from the upper surface 411A of semiconductor substrate 411 to form the first buried semiconductor region 412, this implantation being of the second doping type, opposite to the doping type of semiconductor substrate 411, in this example the implantation is of type N: this implantation may be preceded by the forming of a mask to mask the areas of semiconductor substrate 411 which are not to be N-doped, or even of an alignment mask; an epitaxial growth from the upper surface 411A of semiconductor substrate 411 to form a lightly-doped epitaxial layer 417 of the first doping type, in this example of type P; an etching from the upper surface 417A of epitaxial layer 417 to form a shallow trench in epitaxial layer 417, then a filling of this trench, for example with silicon oxide, to form insulating trench 415; a deep implantation in epitaxial layer 417 through insulating trench 415 to form semiconductor well 416, this implantation being of the first doping type, in this example of type P, this implantation being for example carried out so as to keep a portion 417B of epitaxial layer 417 between semiconductor well 416 and semiconductor substrate 411; a deep implantation into epitaxial layer 417 down to the semiconductor substrate 411, and around portion 417B of epitaxial layer 417, to form the second buried semiconductor region 413, this implantation being of the second doping type, in this example of type N;
an implantation from the upper surface 417A of epitaxial layer 417 to the second buried semiconductor region 413 and around insulating trench 415, to form ring-shaped semiconductor well 414, this implantation being of the second doping type, in this example of type N.

The other features and variants described in relation with FIG. 2, for example the metal stacks 202, the contacts 204, the second portion 201B of the conductive line, may apply to the embodiment of FIG. 4. In particular, similarly to the embodiment of FIG. 2, conductive line 401 further comprises all or part of metal stacks 202 forming part of an interconnection structure 220 (BEOL) positioned above semiconductor substrate 411. Further, similarly to the embodiment of FIG. 2, a first contact 204A and a second contact 204B, positioned on the ring-shaped semiconductor wells 414 of semiconductor structures 410, enable to couple each of semiconductor structures 410 to respectively a first metal stack 202A and a second metal stack 202B, the second metal stacks 202B between the two semiconductor structures 410 being coupled together at the last metallization level M5, or at any other metallization level.

Conductive line 401 comprises: the conductive portions 401A (first portions) formed by the N-doped semiconductor regions 412, 413, 414 of semiconductor structures 410; a second portion 401B between the first portions 401A, the second portion being similar to the second portion 201A described in relation with FIG. 2, the second portion 401B being coupled to each of the first portions 401A by one of the second contacts 204B; and the conductive segments 221A of the first metal stacks 202A, each coupled to one of the first portions 401A by one of the first contacts 204A.

Similarly to what is described in relation with FIG. 2, conductive line 401 may be coupled to a detection circuit (not shown). For example, a first end 401C of conductive line 401 may be coupled to a first terminal of the detection circuit at the first metallization level M1, and a second end 401D of conductive line 401 may be coupled to a second terminal of the detection circuit at the first metallization level M1, but the connection may be performed at any other metallization level. The detection circuit may be configured to detect a change in an electrical parameter in conductive line 401 indicating the presence of a crack. One end of each conductive segment 221A may correspond to one of the first 401C and second 401D ends of conductive line 401.

Such a detection device 400 enables to detect a crack in depth all the way down into a buried semiconductor region of semiconductor structures 410, the first buried semiconductor region 412 or the second buried semiconductor region 413 in the example of FIG. 4. More generally, detection device 400 enables to detect a crack along conductive line 401, between the first buried semiconductor region 412 and upper metallization level M5. To detect a crack, a change in an electrical parameter of conductive line 401 may be determined, for example an increase in the resistance when the conductive line is damaged by a crack in one of semiconductor regions 412, 413, 414, or even an infinite resistance when conductive line 401 is interrupted. A low resistance limit may be defined to determine whether a crack has occurred.

This buried semiconductor region may be located at a depth greater than 4 μm, or even greater than 5 μm. Thus, detection device 400 can detect a crack down to a depth exceeding 5 μm.

According to a variant capable of applying in particular to each of the embodiments of FIGS. 2 to 4, the second metal stacks 202B between the two semiconductor structures 210, 310, 410 may be coupled together by a conductive segment at the first metallization level M1, instead of being at the last metallization level M5. For example, the conductive segments 221B of the second metal stacks 202B may be coupled together, or be a single continuous conductive segment. According to this variant, the second portion 201B′, 301B′, 401B′ of conductive line 201′, 301′, 401′ would run only in the first metallization level M1, as represented by the mixed line in FIGS. 2, 3, 4, and would transit between the second metal stacks 202B at the first metallization level M1. The (first) conductive line 201′, 301′, 401′ could thus run no higher than the first metallization level M1, and no longer up to the last metallization level M5. This variant can thus enable to have less doubt as to the location of a crack detected by conductive line 201′, 301′, 401′, that is, to be able to detect a crack in one of the semiconductor structures or in the semiconductor substrate, and not in interconnection structure 220.

According to a variant that can in particular apply to each of the embodiments of FIGS. 2 to 4, the second metal stacks 202B between the two semiconductor structures 210, 310, 410 may be coupled together by a conductive segment at any other metallization level.

There will now be described in relation with FIGS. 5 to 7 other crack detection devices 500, 600, 700. These other crack detection devices differ from the crack detection devices 200, 300, 400 of FIGS. 2 to 4 mainly in that there is not a single conductive line but two conductive lines: a first conductive line formed in the interconnection structure and in each semiconductor structure, and a second conductive line formed in the interconnection structure (but not in the semiconductor structures). The first conductive line is intended to detect a crack preferably in the semiconductor substrate or in at least one of the semiconductor structures. The second conductive line is intended to detect a crack preferably in the interconnection structure. The first and second conductive lines are preferably insulated from each other. The semiconductor structures of FIGS. 5, 6, and 7 are similar respectively to the semiconductor structures of FIGS. 2, 3, and 4, they are therefore not described again, and keep the same numerical references in the drawings.

In FIGS. 5 to 7, the first conductive line 501, 601, 701 is symbolized by a dotted line, which enables to visualize a conductive path, among a plurality of conductive paths along this first conductive line. The first conductive line 501, 601, 701 is thus not limited to this dotted line. Similarly, the second conductive line 503, 603, 703 is symbolized by a stripe-dot line, which enables to visualize a conductive path, among a plurality of conductive paths along this second conductive line. The second conductive line 503, 603, 703 is therefore not limited to this stripe-dot line.

FIG. 5 is a simplified and partial cross-section view illustrating a crack detection device 500 according to another embodiment.

The crack detection device 500 of FIG. 5 has many features in common with the crack detection device 200 of FIG. 2, and only the differences between the two crack detection devices are detailed in the following description.

The crack detection device 500 of FIG. 5 differs from the crack detection device 200 of FIG. 2 mainly in that the first conductive line 501 transits only at the first metallization level M1 of interconnection structure 520, and in that it comprises a second conductive line 503 which transits through all metallization levels M1-M5 of the interconnection structure 520, but which does not transit through semiconductor structures 210.

Similarly to the interconnection structure 220 of FIGS. 2 to 4, interconnection structure 520 comprises conductive segments 521 at each metallization level M1-M5 and conductive vias 522 between the conductive segments 521 of the different metallization levels M1-M5. Conductive segments 521 and conductive vias 522 are embedded in an insulating layer 523. The conductive segments 521 and the conductive vias 522 from the second metallization level M2 onwards are arranged in a plurality of metal stacks 502. Metal stacks 502 comprise third metal stacks 502A and fourth metal stacks 502B.

The first conductive line 501 includes conductive segments 521A, 521B of the first metallization level M1 and contacts 204, similar to the contacts described in relation with FIGS. 2 to 4. Contacts 204 comprise first contacts 204A coupling each of the semiconductor structures 210 to a first conductive segment 521A, and second contacts 204B coupling each of the semiconductor structures 210 to a second conductive segment 521B. Each of these contact connections is achieved at the first metallization level M1. In other words, the first and second conductive segment 521A, 521B form part of the first metallization level M1. Contacts 204 are positioned on the upper surface 210A of semiconductor structures 210, which corresponds in FIG. 5 to the upper surface 211A of semiconductor substrate 211. In particular, contacts 204 are positioned on the ring-shaped semiconductor wells 214 of semiconductor structures 210, so that each ring-shaped semiconductor well 214 is coupled to first and second conductive segments 521A, 521B.

The second conductive segments 521B between the two semiconductor structures 210 are coupled together at the first metallization level M1, or form a single continuous second conductive segment 521B.

The first conductive line 501 comprises: first portions 501A formed by the N-doped semiconductor regions 213, 214 of semiconductor structures 210, similar to the first portions 201A of FIG. 2; a second portion 501B between the first portions 501A, the second portion being formed by the second conductive segment 521B at the first metallization level M1, similarly to the second portion 201B′ according to the variant previously described in relation with FIGS. 2 to 4, the second portion 501B being coupled to each of the first portions 501A by one of the second contacts 204B; and
the first conductive segments 521A coupled to the first portions 501A by the first contacts 204A.

The first conductive line 501 may be coupled to a first detection circuit, terminals 505A, 505B of which have been shown. For example, a first end 501C of the first conductive line 501 may be coupled to a first terminal 505A of the first detection circuit at the first metallization level M1, and a second end 501D of the first conductive line 501 may be coupled to a second terminal 505B of the first detection circuit at the first metallization level M1. The first detection circuit may be configured to detect a change in an electrical parameter in the first conductive line 501 indicating the presence of a crack in semiconductor substrate 211. One end of each conductive segment 521A may correspond to one of the first 501C and second 501D ends of the first conductive line 501.

The first conductive line 501 passes through the conductive segments 521A, 521B only at the first metallization level M1, so as to detect a crack preferentially in the semiconductor structures 210.

The first conductive line 501 enables to detect a crack in depth all the way down into a buried semiconductor region of semiconductor substrate 211, buried semiconductor region 213, similarly to what is described in relation with FIG. 2. More generally, detection device 500 enables to detect a crack along the first conductive line 501, between buried semiconductor region 213 and the first metallization level M1. To detect a crack, a change in an electrical parameter in the first conductive line 501 may be determined, for example an increase in the resistance when the first conductive line 501 is damaged by a crack in one of semiconductor regions 213, 214, or even an infinite resistance when the first conductive line 501 is interrupted. A first low resistance limit may be defined to determine whether a crack has occurred along the first conductive line 501.

The second conductive line 503 comprises a conductive segment 521E (fifth conductive segment) of the second metallization level M2 of each third metal stack 502A and a conductive segment 521F (sixth conductive segment) of the second metallization level M2 of each fourth metal stack 502B, and other conductive segments 521 of the third to last metallization levels M3-M5 for each fourth metal stack 502B, the conductive segments of each fourth metal stack 502B being coupled together by conductive vias 522. The adjacent fifth and sixth conductive segments 521E, 521F are coupled together by a conductive segment 521D (fourth conductive segment) of the first metallization level M1 and by conductive vias 522, thus coupling the adjacent third and fourth metal stacks 502A, 502B. The fourth conductive segment 521D is insulated from the first and second conductive segments 521A, 521B forming part of the first conductive line 501. Thus, the second conductive line 503 is insulated from the first conductive line 501. The adjacent fourth metal stacks 502B are coupled together at the last metallization level M5 by a conductive segment 521C (seventh conductive segment) which is continuous between these fourth metal stacks.

The second conductive line 503 thus transits between the first metallization level M1 and the last metallization level M5, so as to detect a crack at all the metallization levels of interconnection structure 520.

As a variant, the adjacent third and fourth metal stacks 502A, 502B may be coupled together by a conductive segment of the second metallization level M2. For example, the fifth and sixth adjacent conductive segments 521E, 521F may be directly coupled together. According to this variant, the second conductive line 503 could detect a crack between the second metallization level M2 and the last metallization level M5 of interconnection structure 520.

As a variant, the adjacent fourth metal stacks 502B may be coupled together at a metallization level lower than the last metallization level M5.

The second conductive line 503 may be coupled to a second detection circuit, terminals 506A, 506B of which have been shown. For example, a first end 503C of the second conductive line 503 may be coupled to a first terminal 506A of the second detection circuit at the second metallization level M2, and a second end 503D of the second conductive line 503 may be coupled to a second terminal 506B of the second detection circuit at the second metallization level M2. The second detection circuit may be coupled to the second conductive line at a higher metallization level. The second detection circuit may be configured to detect a change in an electrical parameter in the second conductive line 503 indicating the presence of a crack in interconnection structure 520. One end of each conductive segment 521E may correspond to one of the first 503C and second 503D ends of the second conductive line 503.

To detect a crack, a change in an electrical parameter in the second conductive line 503 may be determined, for example an increase in the resistance or even an infinite resistance. A second low resistance limit may be defined to determine whether a crack has occurred along the second conductive line 503.

The second low resistance limit may be lower than the first low resistance limit.

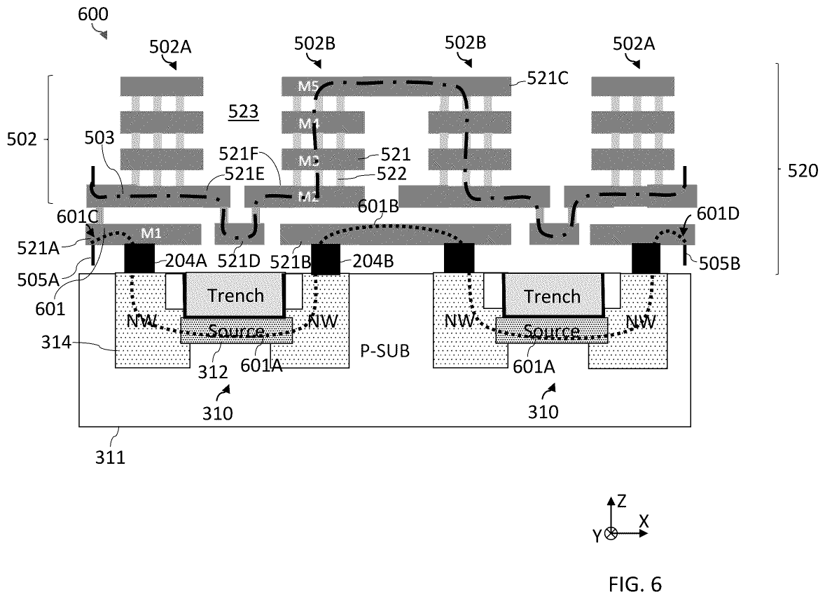

FIG. 6 is a simplified and partial cross-section view illustrating a crack detection device 600 according to another embodiment.

The embodiment of FIG. 6 differs from the embodiment of FIG. 5 in that semiconductor structures 310, similar to those of FIG. 3, replace semiconductor structures 210.

Thus, the first conductive line 601 comprises: first portions 601A formed by the N-doped semiconductor regions 312, 314 of semiconductor structures 310, similar to the first portions 301A of FIG. 3; a second portion 601B between the first portions 601A, the second portion being formed by the second conductive segment 521B at the first metallization level M1, similarly to the second portion 301B′ according to the variant previously described in relation with FIGS. 2 to 4, the second portion 601B being coupled to each of the first portions 601A by one of the second contacts 204B; and
the first conductive segments 521A coupled to the first portions 601A by the first contacts 204A.

The first conductive line 601 takes conductive segments 521A, 521B only at the first metallization level M1, so as to detect a crack preferably in semiconductor structures 310.

The first conductive line 601 may be coupled to a first detection circuit, terminals 505A, 505B of which have been shown. For example, a first end 601C of the first conductive line 601 may be coupled to a first terminal 505A of the first detection circuit at the first metallization level M1, and a second end 601D of conductive line 601 may be coupled to a second terminal 505B of the first detection circuit at the first metallization level M1. The first detection circuit may be configured to detect a change in an electrical parameter in the first conductive line 601 indicating the presence of a crack in semiconductor substrate 311. One end of each conductive segment 521A may correspond to one of the first 601C and second 601D ends of the first conductive line 601.

The first conductive line 601 enables to detect a crack in depth all the way down into a buried semiconductor region of semiconductor substrate 311, buried semiconductor region 312, similarly to what is described in relation with FIG. 3. More generally, detection device 600 enables to detect a crack along the first conductive line 601, between buried semiconductor region 312 and the first metallization level M1. To detect a crack, a change in an electrical parameter in the first conductive line 601 may be determined, for example an increase in the resistance when the first conductive line 601 is damaged by a crack in one of semiconductor regions 312, 314, or even an infinite resistance when the first conductive line 601 is interrupted. A first low resistance limit may be defined to determine whether a crack has occurred along the first conductive line 601.

The second conductive line 503 is similar to that described in relation with FIG. 5, and the described variants may apply.

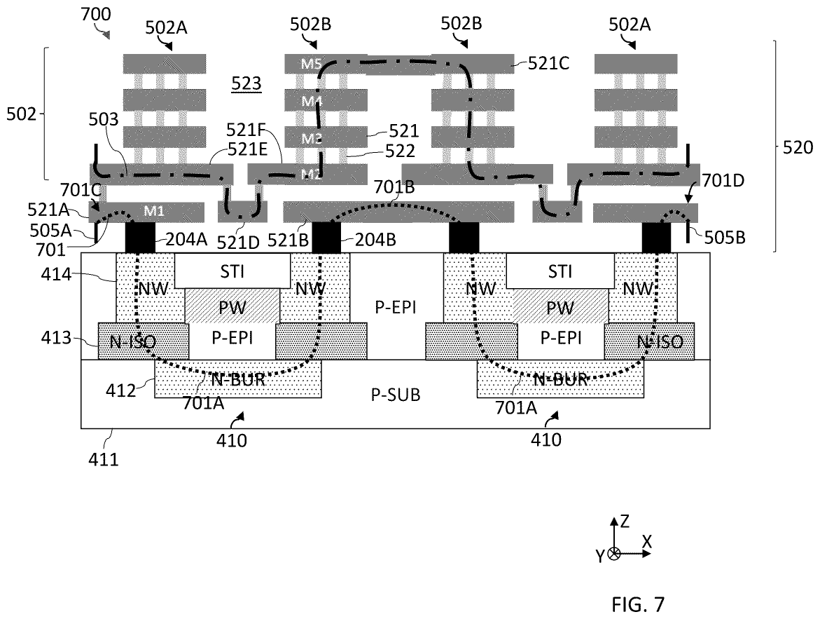

FIG. 7 is a simplified and partial cross-section view of a crack detection device 700 according to another embodiment.

The embodiment of FIG. 7 differs from the embodiment of FIG. 5 in that semiconductor structures 410, similar to those of FIG. 4, replace semiconductor structures 210.

Thus, the first conductive line 701 comprises: first portions 701A formed by the N-doped semiconductor regions 412, 413, 414 of semiconductor structures 410, similar to the first portions 401A of FIG. 4; a second portion 701B between the first portions 701A, the second portion being formed by the second conductive segment 521B at the first metallization level M1, similarly to the second portion 401B′ according to the variant previously described in relation with FIGS. 2 to 4, the second portion 701B being coupled to each of the first portions 701A by one of the second contacts 204B; and the first conductive segments 521A coupled to the first portions 701A by the first contacts 204A.

The first conductive line 701 takes conductive segments 521A, 521B only at the first metallization level M1, so as to detect a crack preferably in semiconductor structures 410.

The first conductive line 701 may be coupled to a first detection circuit, terminals 505A, 505B of which have been shown. For example, a first end 701C of the first conductive line 701 may be coupled to a first terminal 505A of the first detection circuit at the first metallization level M1, and a second end 701D of the first conductive line 701 may be coupled to a second terminal 505B of the first detection circuit at the first metallization level M1. The first detection circuit may be configured to detect a change in an electrical parameter in the first conductive line 701 indicating the presence of a crack in at least one of semiconductor structures 410. One end of each conductive segment 521A may correspond to one of the first 701C and second 701D ends of the first conductive line 701.

The first conductive line 701 enables to detect a crack in depth all the way down into a buried semiconductor region of semiconductor structures 410, for example in the first buried semiconductor region 412 or the second buried semiconductor region 413, similar to what is described in relation with FIG. 4. More generally, detection device 700 enables to detect a crack along the first conductive line 701, between the first buried semiconductor region 412 and the first metallization level M1. To detect a crack, a change in an electrical parameter in the first conductive line 701 may be determined, for example an increase in the resistance when the first conductive line 701 is damaged by a crack in one of semiconductor regions 412, 413, 414, or even an infinite resistance when the first conductive line 701 is interrupted. A first low resistance limit may be defined to determine whether a crack has occurred along the first conductive line 701.

The second conductive line 503 is similar to that described in relation with FIG. 5, and the described variants may apply.

In the examples of FIGS. 2 to 7, four metal stacks have been shown as an example, but there could be more, for example when there are more than two semiconductor structures, or even fewer, for example when there is one semiconductor structure. Many variants of metal stacks, or even of other conductive structures in the interconnection structure, may be envisaged by those skilled in the art.

In all the described embodiments, and more generally for a crack detection device according to an embodiment, or an electronic chip according to another embodiment, the insulating layer of the interconnection structure may be made of an oxide, for example a silicon oxide. As a variant and advantageously, the insulating layer of the interconnection structure may be made of one or a plurality of low-K dielectric materials, that is, materials having a low dielectric constant k as compared with that of silicon dioxide, or even ultra-low-K dielectric materials. Indeed, this type of dielectric material may result in cracks, in which case a detection device is particularly advantageous.

The embodiments enable to detect cracks deep into the semiconductor substrate, or the semiconductor structure formed inside and/or on top of the semiconductor substrate (FEOL level). Embodiments also enable to detect cracks in the interconnection structure (BEOL). Embodiments enable to distinguish a crack at the FEOL level from a crack at the BEOL level, and this, without necessarily increasing the surface area occupied by the detection device.

In the described embodiments, it can be seen that the detection device can be manufactured by using microelectronics manufacturing techniques, for example existing manufacturing lines, according to the manufactured semiconductor structures. For example, the detection device can be manufactured without adding complementary steps, since it is already provided to manufacture the interconnection structure and the semiconductor structures.

The embodiments are adapted to the co-integration of a plurality of, for example different, semiconductor structures formed inside and/or on top of a same semiconductor substrate. All or part of the three semiconductor structures described in FIGS. 2 to 7 may in particular be co-integrated inside and/or on top of a same semiconductor substrate. For example, the co-integration comprises at least one eSTM memory. For example, the semiconductor structures of triple-well type and of vertical-gate type of an eSTM memory may be co-integrated.

The embodiments described hereafter are particularly adapted to the detection of cracks in electronic chips, in particular during the singulation of electronic chips by cutting, for example by laser cutting, of a semiconductor wafer. Thus, the embodiments may have many applications.

The embodiments described hereabove can be used in many types of industrial markets, for example: the automotive industry, for example in the field of automotive electrification or in the field of advanced driver assistance systems (ADAS); the industrial sector, for example in the field of green energy, in the field of infrastructure electrification, of the Internet of Things (IoT) and of smart homes; the personal electronics industry, for example in the field of mobile telephony and of the Internet of Things (IoT), as well as in broadband interfaces; the communications equipment, computer and peripherals industry, for example in the field of infrastructure and data centers, and in the field of low earth orbit (LEO) satellites.

Various embodiments and variants have been described. The person skilled in the art will understand that certain features of these various embodiments and variants could be combined, and other variants will become apparent to the person skilled in the art. In particular, two similar semiconductor structures have been shown inside and/or on top of the semiconductor substrate through which the (first) conductive line of the sensing device transits. A plurality of other variants may be envisaged by those skilled in the art. According to a variant, the (first) conductive line of the sensing device may transit through a single semiconductor structure. In this case, the conductive line may only transit as far as the first metallization level of the interconnection structure. According to another variant, different semiconductor structures may be formed inside and/or on top of the semiconductor substrate, and the (first) conductive line of the detection device may then transit through these different semiconductor structures.

Finally, the practical implementation of the described embodiments and variants is within the abilities of those skilled in the art, based on the indications given above.

What is claimed is:

1. A device comprising:
a first conductive line for detecting a crack in an at least one semiconductor structure, the first conductive line being comprised within an interconnection structure and within at least one semiconductor structure, the interconnection structure being coupled to a first surface of the at least one semiconductor structure, the first conductive line comprising at least one first conductive segment and at least one second conductive segment, the at least one first and second conductive segments being of a first metallization level of the interconnection structure and being electrically insulated from each other by an insulating layer; and
a conductive region buried deep into each semiconductor structure, the buried conductive region being coupled to one of the at least one first conductive segment and one of the at least one second conductive segment, an insulating region being positioned between the first surface of each semiconductor structure and the buried conductive region.

2. The device according to claim 1, wherein the semiconductor substrate is doped with a first conductivity type, the buried conductive region being a doped semiconductor region of a second conductivity type opposite to the first conductivity type.

3. The device according to claim 2, wherein each semiconductor structure comprises:
a doped semiconductor well of the second conductivity type, the doped semiconductor well extending in depth from the first surface of the semiconductor structure so as to electrically couple the first surface and the buried conductive region;
conductive elements coupled to the first surface of the semiconductor structure, the conductive elements comprising a first conductive element coupling the semiconductor well to the first conductive segment, and a second conductive element coupling the semiconductor well to the second conductive segment.

4. The device according to claim 1, wherein the buried conductive region is at a depth greater than 0.5 μm.

5. The device according to claim 1, wherein each first conductive segment is included in a first metal stack comprising a plurality of metallization levels of the interconnection structure, and each second conductive segment is included in a second metal stack comprising a plurality of metallization levels of the interconnection structure.

6. The device according to claim 1, wherein the at least one semiconductor structure comprises a plurality of semiconductor structures, the at least one first conductive segment comprising a plurality of first conductive segments and the at least one second conductive segment comprising a plurality of second conductive segments, the second conductive segments between two adjacent semiconductor structures among the semiconductor structures being coupled together in the interconnection structure.

7. The device according to claim 6, wherein the second conductive segments are coupled together at the first metallization level of the interconnection structure.

8. The device according to claim 6, wherein the second metal stacks between the two adjacent semiconductor structures are coupled together by a third conductive segment of a metallization level of the interconnection structure higher than the first metallization level.

9. The device according to claim 1, wherein the first conductive line is configured to detect a crack in the interconnection structure.

10. The device according to claim 1, further comprising a second conductive line for detecting a crack in the interconnection structure, the second conductive line being comprised within the interconnection structure and being distinct from the first conductive line.

11. The device according to claim 10, wherein the second conductive line comprises:
at least one fourth conductive segment of the first metallization level of the interconnection structure, each fourth conductive segment being insulated from the at least one first and at least one second conductive segment by the insulating layer;
at least one fifth conductive segment of a metallization level of the interconnection structure higher than the first metallization level;
at least one sixth conductive segment of a metallization level of the interconnection structure higher than the first metallization level; and
each fourth conductive segment coupling one of the at least one fifth conductive segment to one of the at least one sixth conductive segment.

12. The device according to claim 11,
wherein each fifth conductive segment is included in a third metal stack comprising a plurality of metallization levels of the interconnection structure from the second metallization level, or
wherein each sixth conductive segment is included in a fourth metal stack comprising a plurality of metallization levels of the interconnection structure from the second metallization level.

13. The device according to claim 10, wherein the second conductive line comprises a first end coupled to a first terminal of a second detection circuit and a second end coupled to a second terminal of the second detection circuit, so as to measure an electrical signal in the second conductive line to determine a presence of a crack.

14. The device according to claim 1, wherein the first conductive line comprises a first end coupled to a first terminal of a first detection circuit and a second end coupled to a second terminal of the first detection circuit, so as to measure an electrical signal in the first conductive line to determine a presence of a crack.

15. The device according to claim 14, wherein the second terminal of the second detection circuit is electrically insulated from the second terminal of the first detection circuit.

16. The device according to claim 1, wherein the insulating layer comprises a material with a lower dielectric constant than the dielectric constant of silicon dioxide.

17. An electronic chip comprising:
a semiconductor substrate;
at least one semiconductor structure disposed within/over the semiconductor substrate;
an interconnection structure coupled to a first surface of the at least one semiconductor structure; and
a crack detection device comprising:
a first conductive line for detecting a crack in the at least one semiconductor structure, the first conductive line being comprised within the interconnection structure and within the least one semiconductor structure, the first conductive line comprising at least one first conductive segment and at least one second conductive segment, the at least one first and second conductive segments being of a first metallization level of the interconnection structure and being electrically insulated from each other by an insulating layer; and
a conductive region buried deep into each semiconductor structure, the buried conductive region being coupled to one of the at least one first conductive segment and one of the at least one second conductive segment, an insulating region being positioned between the first surface of the semiconductor structure and the buried conductive region.

18. The electronic chip according to claim 17, wherein the at least one semiconductor structure comprises a plurality of semiconductor structures, at least one semiconductor structures among the semiconductor structures comprising a vertical gate structure of a buried selection transistor of an integrated memory cell with a trench selection transistor.

19. The electronic chip according to claim 17, wherein the crack detection device is positioned at the periphery of the electronic chip.

20. A method comprising:
transmitting a first electrical signal at a first end of the first conductive line;
receiving the first electrical signal at a second end of the first conductive line;
measuring a first resistance value of the received first electrical signal; and
comparing the measured first resistance value with a first low resistance limit to determine the presence of a crack in the first conductive line.
